(19) United States
(12) Patent Application Publication
(10) Pub. No.: US 2011/0250466 A1
(43) Pub. Date: Oct. 13, 2011

(54) METALLIC COMPONENT, IN PARTICULAR ROLLING BEARING, ENGINE OR TRANSMISSION COMPONENT

(75) Inventors: Claus Muller, Eckental (DE); Peter Schuster, Zirndorf (DE)

(73) Assignee: SCHAEFFLER TECHNOLOGIES GMBH & CO. KG, Herzogenaurach (DE)

(21) Appl. No.: 13/139,829

(22) PCT Filed: Mar. 19, 2010
(86) PCT No.: PCT/EP10/53628

§ 371 Date: Jun. 15, 2011

(30) Foreign Application Priority Data
Mar. 21, 2009 (DE) 102009014344.0

(51) Int. Cl. B32B 15/00; C23C 16/00; B05D 1/36; B32B 7/04; B05D 3/12

(52) U.S. Cl. 428/609; 428/615; 428/457; 427/328; 427/405; 427/250; 427/331

(57) ABSTRACT

A metallic component, in particular a rolling bearing, engine or transmission component, having a component body and at least one functional surface thereof that interacts with another element. Only the functional surface (7) is formed from an amorphous metal (6).

### FIELD OF THE INVENTION

The invention relates to a metallic component, in particular, a rolling bearing, engine, or transmission component, with a component body and at least one functional surface that is provided on this component body and interacts with a different element.

### BACKGROUND

Metallic components are used in very different constructions, and, merely as examples, roller bearing components (bearing rings, sleeves, etc.), engine components, such as, for example, tappets or cams or shafts or transmission components are noted. The mechanical properties, but also physical or chemical properties depend centrally on the component material that is used, that is, the metal or steel that is being used. Special requirements are placed on the strength and hardness of the material. The influence with respect to actual application purposes is performed, for example, through the addition of special alloy elements or through the introduction of nitrogen into the component, etc. Nevertheless, it is not always possible to realize the demanded material properties, for example, a high strength with a simultaneously comparatively low E-modulus in the area of the functional surface, that is, a relatively high elasticity in the functional surface area.

### SUMMARY

The invention is thus based on the objective of providing a metallic component that has novel material properties with respect to previously known metallic components.

To meet this objective, according to the invention it is provided for a metallic component of the type noted above that only the functional surface is formed from an amorphous metal.

The metallic component according to the invention distinguishes itself through a material combination. The central part of the component is the component body that is made from an arbitrary steel, such as that needed for satisfying the basic requirements of the component (strength, corrosion resistance, etc.). The component body is still the central property-determining element of the component. According to the invention, however, the component also consists of a second material, namely an amorphous metal that forms the functional surface or with which the functional surface is constructed. Here, a material combination is used, wherein each material has and makes available its specific material properties. For example, such a component according to the invention distinguishes itself by a high strength resulting from the material properties of the component body, while also providing a sufficiently high elasticity in the area of the functional surface resulting from the linear-elastic properties of the amorphous metal.

Although it is known from DE 10 2004 034 547 A1 to produce roller bearing rings or roller bodies from an amorphous metal, these are formed completely from this amorphous metal, that is, such a component makes available only the material properties of the amorphous metal. The same applies with respect to metallic components that consist completely from steel of the same type. They also exhibit only the material properties that the sole material, namely the metal, makes available, whether with respect to mechanical, physical, or chemical terms. In contrast, the metallic component according to the invention distinguishes itself through an extremely broad material property combination resulting from the combination of the two materials.

In the component according to the invention, the condition that only the functional surface is formed from an amorphous metal further offers the advantage that, with respect to the size of the metallic components that can be produced, with the amorphous metal functional surfaces, there are no longer size limitations that are given in previously known components consisting of only amorphous metal (as known, for example, from DE 10 2004 034 547 A1) due to the high cooling rate needed in production, especially with respect to the limited wall thickness. Also, work can be performed with significantly less amorphous metal material, which reduces the production costs.

Amorphous metals, which are also called metallic glasses below, are alloys that have an amorphous structure at the atomic level, that is, no crystalline structure, as is applicable for metals. This very unusual atomic arrangement for metals leads to special physical and mechanical properties. Such amorphous metals are in general more corrosion resistant and stronger than conventional metals. In the scope of the production or working of the starting material, the natural crystallization is prevented by very rapid cooling of the molten material, so that the movement is taken from the atoms before they can assume the crystal arrangement or metal lattice structure. However, this requires that the atomic structure or the atoms present in the material have different sizes, so that for extremely rapid cooling it does not result in “movement obstacle” and no crystal arrangement, which is why amorphous structures can be achieved only for special alloys. Typically they consist of several different elements, wherein usually at least three fundamentally different atom sizes are represented.

For the amorphous metal to be used, the starting material, is to be determined through suitable selection of the alloy composition (“alloy design”), wherein a sufficiently high ductility and fault tolerance (fracture toughness), the realization of a sufficiently low processing temperature that is suitable, e.g., for injection molding, a sufficiently low crystallization trend of the molten metal during the cooling, as well as economical and available starting materials, should be taken into account as selection parameters. Usable alloys consist advantageously, but not exclusively, from alloy elements, such as Fe, Ni, Al, Si, Zr, Ti, Cu, Cr, Sn, Co, Nb, Ce, Ca, Mg, B, C, or N. The invention is not limited, however, to the above elements, a certain number or a certain atomic percentage of each alloy element, and the element combination could also be arbitrary, as long as the resulting amorphous metal satisfies the desired processing and target properties placed on the metal or the component to be produced.

As already described, amorphous metals exhibit excellent mechanical, physical, and chemical properties. They are, in general, significantly harder than conventional metals, that is, harder than steel that is typically used for the production of cages. In contrast, they are also significantly more corrosion resistant and stronger. They exhibit a linear-elastic behavior in a wide range, i.e., under alternating loading, a spring deflection with minimal damping and minimal internal friction. This is a desirable property especially for the reaction between the component and the other component interacting with it (e.g., bearing ring and roller body). Obviously, a sufficiently high temperature resistance is also given. The high strength connected with a relatively low density that can be achieved according to the alloy partners also allows suitability for very high rotational speeds, and excellent friction pairs can also be found.

Although very different alloy compositions as already described can be formed, for example, from the alloy elements named above that allow, according to the composition, the setting of very different mechanical, chemical, and physical properties of the amorphous metal that can be obtained, a few examples of special alloy compositions and their properties shall be disclosed below.

A first example for an amorphous glass or metal glass for structural applications is Zr61.7Al8Ni13Cu17Sn0.3, wherein the numbers after each alloy element specify its percentage in atom % within the alloy. This amorphous metal is significantly more ductile in comparison to other amorphous metals. It exhibits practically no susceptibility to fracture failures, which is of central importance for the application according to the invention as a functional surface material.

A second example of an especially well suited amorphous metal is Ni53Nb20Ti10Zr8Co6Cu3. This amorphous metal has very good corrosion resistance connected with a very high strength and, in comparison to steel, a significantly higher resistance with respect to rolling friction.

Amorphous metals of the composition (Cu0.6Af0.25Ti0.15)90Nb10 exhibit, in hydrochloric acid, as well as in NaCl solution, a significantly higher corrosion resistance relative to conventional bronze for a simultaneously high compression strength (ca. 2600 MPa) as well as a very high plastic elongation of ca. 12% for amorphous metals.

Even higher fracture strengths (ca. 4000 MPa) were determined for amorphous metals of the system Fe—Co—Ni—B—Si—Nb for a high E-modulus of ca. 190 GPa as well as a hardness of ca. 1200 HV for amorphous metals.

The mentioned examples are merely examples and should show that very different alloy compositions can be found that each have different focuses on properties. According to the field of use of the component to be produced, an amorphous metal could be used that has optimal mechanical, chemical, and physical properties with respect to the desired application, like those that previously used materials used for the formation of “single-component” components for the application purpose do not have or not in the form achievable according to the invention.

At this point it is to be noted that, under the term “amorphous metal,” it is to be understood in the scope of the present invention that the amorphous metal or the metal glass could be both completely amorphous or also partially crystallized (out). Possible examples for functional surfaces that could be formed from the amorphous metal are raceways for roller bearings, contact regions for seals, sleeves, inserts for linear guides, contact faces for chain guides or sliding rails, etc. are to be named only as examples. This listing, however, is not conclusive.

The amorphous metals exhibit, in addition to the advantages already mentioned above of high elasticity for simultaneously high strength, also excellent wear and corrosion resistance, which is required by the comparatively low E-modulus, as well as the fact that the metal glasses have no regular metal structure and thus no grain boundaries. Another excellent property is that, during the cooling of the molten metal into the solid state, there is no crystallization shrinkage and thus shaping to final contour dimensions is possible.

In order to provide for a sufficiently strong connection between the component body and the metal glass functional surface, one development of the invention provides for profiling, in particular, roughening or scoring, of the surface of the component body on which the amorphous metal is deposited or applying an adhesive layer in the form of a base or intermediate layer. The surface profiling provides for an enlargement of the surface area of the component body and thus for an enlargement of the adhesive surface. The adhesive layer could provide for an improved chemical or physical adhesion.

With respect to the application of the amorphous metal, different possibilities are conceivable. According to a first construction, the amorphous metal could be cast. Here, the molten metal glass is cast on or around or in the component body, wherein one or more of the component surfaces function simultaneously as a molding tool against which casting is performed. The molding tool surfaces for the cast functional surface(s) are completed by additional tool molding surfaces that are adapted to the component shape. The shaping of the component and the functional surface, as well as that of the tool, is realized such that removal shaping, e.g., back cutting, is guaranteed. For example, the tool could be equipped with slides like those known from injection molding technology. As the casting method, no-pressure casting or diecasting (metal-glass injection molding) could be used.

An alternative to casting is to inject the amorphous metal. Here, the correspondingly treated component is coated with the amorphous metal either through thermal injection (injection of molten material droplets at high temperature) or through low-temperature injection (the so-called kinetic metallization). Another form of injection is “spray forming,” which is understood to be the original shaping of thicker cross sections—in comparison with thermal injection—by injection of molten material droplets on a correspondingly treated component body.

A third application alternative provides applying the amorphous metal in a PVD method, that is, depositing it from the gas phase, wherein here optionally an intermediate step can be performed, in order to produce, for example, by means of a cast, a solid metal-glass target material. In the PVD process, the metal-glass target is evaporated and this vapor is deposited on the optionally pretreated functional surface.

In addition to the metallic component itself, the invention further relates to a method for the production of such a metallic component that distinguishes itself in that a surface section of the component body is coated with an amorphous metal forming a functional surface of the component.

The surface section is provided according to the invention, before application of the amorphous metal, with a profiling, in particular, with a roughened section or with an adhesive layer.

For application of the amorphous metal, either a casting method, in particular, no-pressure casting, injection molding, or also diecasting could be used; an injection method is also conceivable, especially thermal injection or low-temperature injection or spray forming, as well as PVD deposition.

What is important, in principle, is to prevent to the greatest possible extent an oxidation of the molten metal glass by suitable protective-gas atmospheres or vacuum.

The deposited amorphous metal can be finished mechanically in the area of the functional surface, in order to achieve the final contours, wherein this finishing work is extremely minimal due to the minimal shrinkage of the amorphous metal during cooling. Finishing work through turning, drilling, milling, grinding, or honing would also be conceivable.

### BRIEF DESCRIPTION OF THE DRAWINGS

An embodiment of the invention is shown in the drawings and will be described in detail below. Shown are:

FIG. 1 is a block diagram for explaining the sequence of production of a metallic component in the form of an angular contact ball-bearing ring with a functional surface made from an amorphous metal, produced through casting,

FIG. 2 is a block diagram of the production of a cylinder roller bearing ring with a functional surface made from an amorphous metal with rotating tool,

FIG. 3 is another block diagram of the production of a cylinder roller bearing ring with a functional surface made from an amorphous metal with rotating tool in addition to a cross-sectional view of the molding tool,

FIG. 4 is a block diagram for the production of a cylinder roller bearing ring with a functional surface made from an amorphous metal of a second embodiment, and

FIG. 5 is a block diagram of a cylinder roller bearing ring with a functional surface made from an amorphous metal produced according to a third variant.

### DETAILED DESCRIPTION OF THE PREFERRED EMBODIMENTS

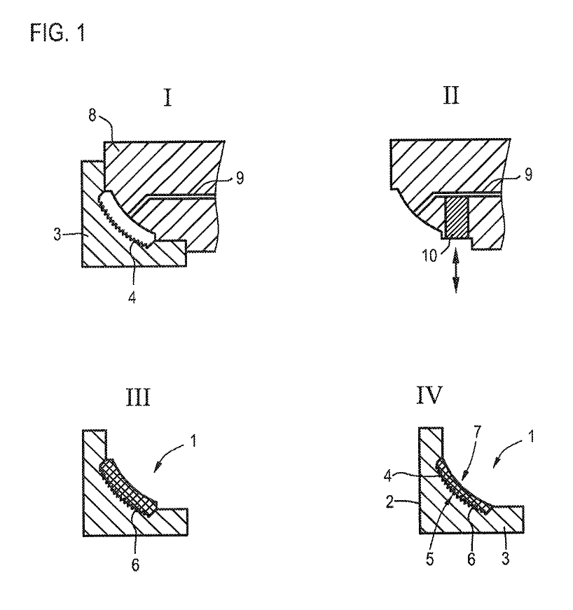

In the form of four sub-steps I-IV, FIG. 1 shows the basic production sequence for the formation of an angular contact ball-bearing ring 2, as is shown in FIG. 1 in the sub-figure IV. The metallic component 1 in the form of the angular contact ball-bearing ring 2 comprises a metallic component body 3 made from a steel selected with respect to the application, wherein here any arbitrary steel could be used that has the desired material properties. A cavity 4 that has, e.g., a surface profiling 5 on its free surface is prefabricated close to the final contours on the component body 3. This surface profiling could be realized by roughening or scoring or the like; the application of an adhesive or base layer would also be conceivable.

The cavity 4 is filled, as shown, with an amorphous metal 6. The amorphous metal forms the functional surface 7 of the component 1, wherein, in the illustrated example, balls of the angular contact ball-bearing ring to be produced with this component 1 roll on this surface.

As is to be seen in the FIG. 1, sub-figure I, for application of the amorphous metal 6, the component body 3 that is supported on the bottom and on the sides, which is not shown here in more detail, is placed against a molding tool 8 that has a feed channel 9 by which the molten amorphous metal 6 is fed. The channel outlet is opposite the cavity 4, so that the discharged, liquid amorphous metal can flow directly into the cavity 4.

As is shown in FIG. 1, sub-figure II, in addition to the molding tool 8, a slide 10 could also be provided that, when necessary, seals the area between the liquid metal and tool or with which under cutting can be represented.

After application of the molten amorphous metal, this is cooled, that is, brought into a solid state, wherein no crystallization shrinkage is produced. The molding tool 8 itself, which is formed, for example, of a metal with high heat conductivity, such as, e.g., copper, or of a ceramic with high conductivity, such as, e.g., silicon carbide, and optionally has available cooling devices, ensures for a rapid heat discharge.

FIG. 1, sub-figure III shows the component 1 after cooling of the amorphous metal 6. It is clear that this metal could protrude somewhat. In this case, finishing work is needed in order to produce the final contours as shown in the sub-figure IV. This could be realized, for example, through grinding. However, net-shape forming without excess is also possible, so that the finishing work can be eliminated. The functional surface 7 is clearly formed exclusively from the amorphous metal, so that, in the area of the functional surface 7, the material properties of the amorphous metal are provided or determined, while otherwise the component body 3 or the material itself determines the properties.

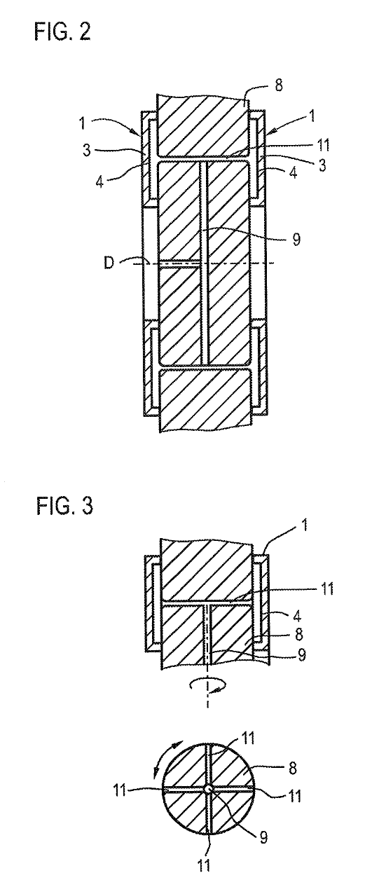

FIG. 2 shows a production example for a cylinder roller bearing ring. Shown here are two components 1 in the form of the cylinder bearing rings, each of which has a cavity 4. They lie on both sides of a molding tool 8 that can rotate about an axis of rotation D. The amorphous metal is fed by a central feed channel 9 in the molten state, in the illustrated example the feed channel 9 branches into four transverse channels 11, each of which leads to the peripheral, annular cavity 4. During the introduction of the amorphous metal, the molding tool 8 rotates, so that it is guaranteed that the cavity 4 is completely filled, because the transverse channels 11 travel along the cavity 4. Also here, the surface of the cavity 4 can be profiled, for example, roughened or provided with a base.

After complete filling of the cavities 4 and after cooling of the metal 6, the bearing rings are removed again and the surface of each metal-glass layer is finished, in order to form the corresponding functional surface.

FIG. 3 shows an alternative, wave-like, rotating molding tool 8 (at the top in the longitudinal section, at the bottom in the transverse section) that rotates about its longitudinal axis relative to the stationary component 1. It likewise has a feed channel 9 that branches into transverse channels 11 that open, in turn, into the cavity 4 of the component 1, here also in the form of a cylinder roller bearing ring, so that the fed amorphous metal can spread uniformly in the cavity, filling this cavity. After cooling, the bearing ring could be finished for formation of the functional surface—naturally several bearing rings could be filled simultaneously by the molding tool, all that must be provided is a corresponding number of transverse channels 11 distributed across the tool length.

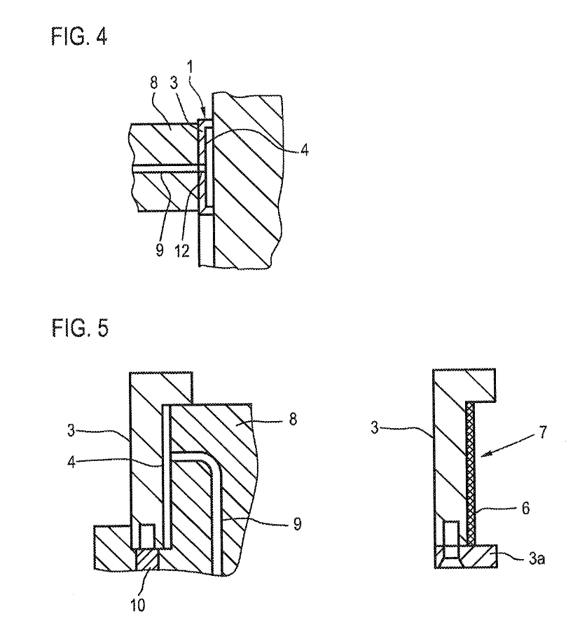

Instead of a rotating molding tool 8, a stationary molding tool 8 could also be used, see FIG. 4, which is moved against the component 1, here, the bearing ring provided with the cavity 4. The bearing ring has a drilled hole 12 into which the feed channel 9 opens and by which the metal is fed here only at one point on the ring periphery, with this metal spreading, because it is molten, into the entire annular cavity 4.

Finally, FIG. 5 shows another example for the production of a metallic component 1 in the form of a cylinder roller bearing ring that is here, however, a two-part construction. It consists of a large component body 3 and a second component body 3a screwed on this large component body after application of the amorphous metal 6. Here, a molding tool 8 with a feed channel 9 is also used that opens in the area of the cavity 4. The cavity 4 of the component body 3 with an L-shaped cross section is closed on the bottom side by a slide 10. After filling the cavity 4 with the amorphous metal 6 and after this metal cools, the mold is opened again and the slide 10 is removed, after which the finishing work of the metal glass 6 is performed and the functional surface is worked into its final contours, after which the second component body part 3a that is here constructed as a ring is set on top or screwed on. It would also be conceivable to snap or glue this ring in place, etc.

The illustrated examples of the roller bearing components are merely exemplary for the different components. These are obviously non-restrictive. Instead, the components could be of an arbitrary nature.

Through the high elasticity of the amorphous metal, for example, with respect to the example of the roller bearing components as described above, elasticity in the area of the functional surface can be realized, wherein spring deflection of the roller bodies is possible and a wider loading zone is realized in the roller contact, that is, the local loading of the bearing rings is reduced, increasing their service lives. For example, there is furthermore the possibility to produce the roller bodies either completely from metal glass or—according to the invention—from a metallic, central component body with deposited, outer metal-glass rolling layer. In this case, if both the rolling surface (=functional surface) of the roller body and also the functional surface of the ring are made from an amorphous metal, due to the two-sided spring deflection a significantly smaller energy absorption could be achieved (lower damping, higher elasticity) compared with typical, metallic roller bodies, e.g., from 100Cr6, that is, the deformation work delivered by the metal-glass roller body is less than that of a pure metallic roller body. The friction heat generated by the delivered elastic deformation work of the bearing components is also lower and the operating temperature is reduced, increasing the duration of grease use and thus the duration of bearing friction.

### LIST OF REFERENCE SYMBOLS

1 Component
1a Component body
2 Angular contact ball-bearing ring
3 Component body
3a Component body part
4 Cavity
5 Surface profiling
6 Amorphous metal
7 Functional surface
8 Molding tool
9 Feed channel
10 Slide
11 Transverse channel
12 Drilled hole

1. Metallic component of a roller bearing, engine, or transmission component, comprising a component body and at least one functional surface that is provided on the body and interacts with another element, only the functional surface is formed from an amorphous metal.

2. Metallic component according to claim 1, wherein a surface of the component body on which the amorphous metal is deposited is profiled or is coated with an adhesive layer.

3. Metallic component according to claim 2, wherein the amorphous metal is cast in place.

4. Metallic component according to claim 2, the amorphous metal is sprayed in place.

5. Metallic component according to claim 2, wherein the amorphous metal is deposited in a PVD method.

6. Method for the production of a metallic component comprising providing a component body, and coating only a surface section of the component body with an amorphous metal that forms a functional surface of the component.

7. Method according to claim 6, further comprising providing the surface section with a profiling or with an adhesive layer or intermediate layer before application of the amorphous metal.

8. Method according to claim 7, wherein the amorphous metal is deposited by casting through no-pressure casting, through injection molding, or through diecasting.

9. Method according to claim 7, wherein to the amorphous metal is deposited by injection through thermal spraying or low-temperature spraying or spray forming.

10. Method according to claim 7, wherein the amorphous metal is deposited by PVD.

11. Method according to claim 7, wherein the deposited amorphous metal is finished mechanically in an area of the functional surface.
